(19) United States
(12) Patent Application Publication
(10) Pub. No.: US 2024/0096949 A1
(43) Pub. Date: Mar. 21, 2024

(54) DIODES IN NANOSHEET TECHNOLOGY

(71) Applicant: International Business Machines Corporation, Armonk, NY (US)

(72) Inventors: Ruilong Xie, Niskayuna, NY (US); Kangguo Cheng, Schenectady, NY (US); Julien Frougier, ALBANY, NY (US); Chanro Park, Clifton Park, NY (US); Min Gyu Sung, Latham, NY (US)

(21) Appl. No.: 17/946,002

(22) Filed: Sep. 15, 2022

(51) Int. Cl. H01L 29/06; H01L 27/06; H01L 29/423; H01L 29/66; H01L 29/775; H01L 29/786; H01L 29/861

(52) U.S. Cl. CPC H01L 29/0673; H01L 27/0629; H01L 29/42392; H01L 29/66136; H01L 29/66439; H01L 29/775; H01L 29/78696; H01L 29/861; H01L 29/6653; H01L 29/66545; H01L 29/66553; H01L 29/6656

(57) ABSTRACT

A nanosheet diode includes a bookend structure and a central structure. The bookend includes a first semiconductor that is doped as one of the anode and the cathode of the diode, and includes a left block, a right block, and a first stack of spaced-apart nanosheets that horizontally connect the left and right blocks. The central structure includes a second semiconductor that is doped as the other of the anode and the cathode of the diode, and includes a front block, a rear block, and a second stack of nanosheets that are interleaved crosswise into spaces between the first stack of spaced-apart nanosheets and that horizontally connect the front and rear blocks. The bookend structure directly contacts top, bottom, and end surfaces of the second stack of nanosheets of the central structure.

### BACKGROUND

The present invention relates to the electrical, electronic, and computer arts, and more specifically, to fabricating nanosheet semiconductor devices.

Previously, diodes have been fabricated alongside transistors in nanosheet technology by depositing a stack of alternating layers of two materials over a substrate and defining field-effect transistor (FET) and diode regions and depositing a mask. The mask covers only the FET region while leaving the diode region uncovered. The prior-art process further includes doping the material in the diode region with a dopant, implanting epitaxial material with another dopant to form PN junctions, and stripping the mask from the structure. The prior-art process still further includes forming a metal gate conductor over the FET region, and depositing a metal over the structure to create terminals. In the diode region, according to the prior-art process, dielectric spacers remained embedded between a p-doped semiconductor structure and an n-doped semiconductor structure.

### SUMMARY

Principles of the invention provide techniques for forming diodes in nanosheet technology.

An exemplary semiconductor structure, according to an aspect of the invention, includes a nanosheet diode that has an anode and a cathode. The nanosheet diode includes: a bookend structure that is doped as one of the anode and the cathode of the diode, and that comprises a left block, a right block, and a first stack of spaced-apart nanosheets that horizontally connect the left and right blocks; and a central structure that is doped as the other of the anode and the cathode of the diode, and that comprises a front block, a rear block, and a second stack of nanosheets that are interleaved into spaces between the first stack of spaced-apart nanosheets and that horizontally connect the front and rear blocks. The bookend structure directly contacts top, bottom, and end surfaces of the second stack of nanosheets of the central structure.

According to another aspect, an exemplary method for forming a nanosheet diode includes forming a bookend structure, which includes a first semiconductor that is doped as one of an anode and a cathode of the diode, and which includes a left block, a right block, and a first stack of spaced-apart nanosheets that horizontally connect the left and right blocks; and forming a central structure, which includes a second semiconductor that is doped as the other of the anode and the cathode of the diode, and which includes a front block, a rear block, and a second stack of nanosheets that are interleaved crosswise into spaces between the first stack of spaced-apart nanosheets and that horizontally connect the front and rear blocks. The bookend structure directly contacts top, bottom, and end surfaces of the second stack of nanosheets of the central structure.

In view of the foregoing, techniques of the present invention can provide substantial beneficial technical effects. For example, one or more embodiments provide a diode formed in nanosheet technology, with enhanced conductivity relative to previous diodes of similar scale and technology. Some embodiments may not have this/these potential advantage(s) and this/these potential advantage(s) are not necessarily required of all embodiments. These and other features and advantages of the present invention will become apparent from the following detailed description of illustrative embodiments thereof, which is to be read in connection with the accompanying drawings.

### BRIEF DESCRIPTION OF THE DRAWINGS

FIG. 1 through FIG. 4 depict, in schematics, a nanosheet semiconductor structure that includes a diode, according to exemplary embodiments.

FIG. 5 depicts, in a flowchart, steps in an exemplary method for fabrication of the semiconductor structure that is shown in FIG. 1.

FIG. 6 through FIG. 9 depict, in schematics, a preliminary structure in the exemplary method that is shown in FIG. 5.

FIG. 10 through FIG. 45 depict, in schematics, intermediate structures that are produced by steps of the exemplary method that is shown in FIG. 5.

### DETAILED DESCRIPTION

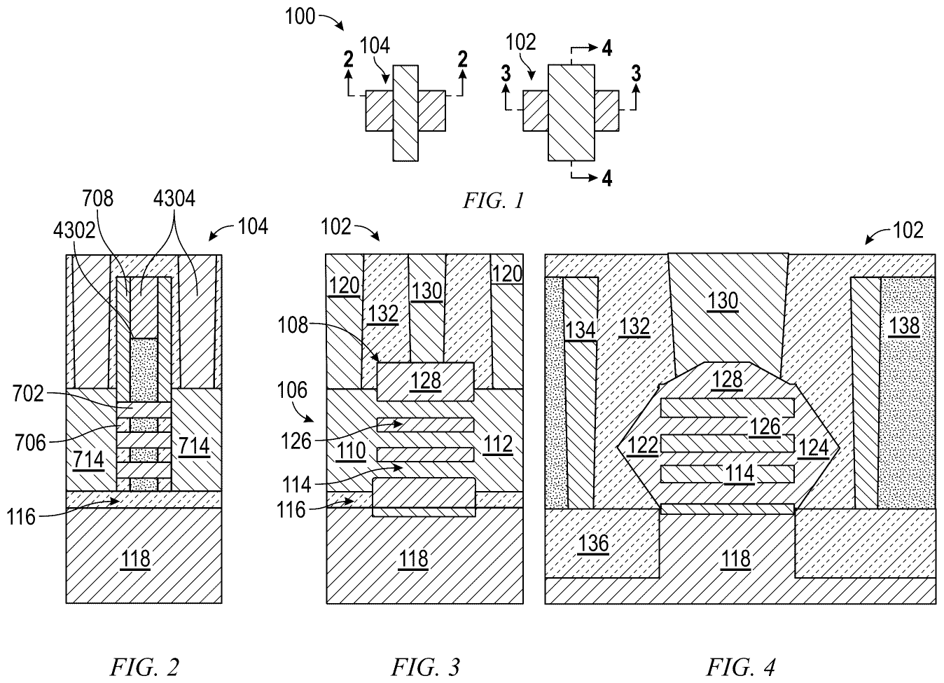

FIG. 1 through FIG. 4 depict, in schematics, a nanosheet semiconductor structure 100 that includes a diode 102 and a transistor 104. FIG. 2, FIG. 3, and FIG. 4 are taken along view lines 2, 3, and 4, respectively, in FIG. 1. The diode 102 includes a bookend structure 106 and a central structure 108. Either of the bookend structure 106 or the central structure 108 may be doped as the anode of the diode 102, while the other of the two structures may be doped as the cathode. In one or more non-limiting exemplary embodiments, the bookend structure 106 and the central structure 108 both include silicon; in some cases, they both consist essentially of silicon. In one or more non-limiting exemplary embodiments, the anode is doped with a p-dopant—in some cases, the p-dopant is selected from the list consisting of boron, aluminum, gallium and indium. In one or more non-limiting exemplary embodiments, the cathode is doped with an n-dopant—in some cases, the n-dopant is selected from the list consisting of antimony, arsenic and phosphorous.

The bookend structure 106 includes a left block 110 and a right block 112, with nanosheets 114 that extend horizontally between and connect the left and right blocks 110, 112. In this disclosure, terms such as “left,” “right,” “front,” “rear,” “horizontal,” and “vertical” are relative to the drawings of the disclosure and do not mandate that an actual product must be oriented or configured so that particular components necessarily are to the “left” or “right,” etc. In one or more embodiments, bottom dielectric isolation 116 is provided beneath the left and right blocks 110, 112 to electrically separate them from a substrate 118. In one or more embodiments, the substrate 118 also includes silicon; in some cases, it consists essentially of silicon.

Top contacts 120 electrically connect the left and right blocks 110, 112 to a back-end-of-line (BEOL) layer of the semiconductor device 100. The BEOL layer is not shown, to avoid clutter; BEOL layers and electrical connections to forward- or reverse-biased diodes, are within the skilled worker's knowledge.

The central structure 108 includes a front block 122, a rear block 124, and horizontal nanosheets 126 that extend horizontally between and connect the front and rear blocks. The nanosheets 126 are interleaved with the nanosheets 114, in a generally crosswise fashion. The central structure 108 also includes a top block 128. A top contact 130 electrically connects the top block to the BEOL layer (not shown) of the semiconductor device 100.

An interlayer dielectric 132, gate cuts 134, and shallow trench isolation 136 electrically separate the diode 102 from gate stacks 138 of adjoining transistors (not shown in detail).

The transistor 104 includes the substrate 118, source/drain structures 714, a gate stack 4302, and source/drain contacts 4304. The transistor 104 is, in and of itself, conventional, and is further described only as it relates to fabrication processes that affect both the diode 102 and the transistor 104. Elements 702, 706, 708 are discussed below.

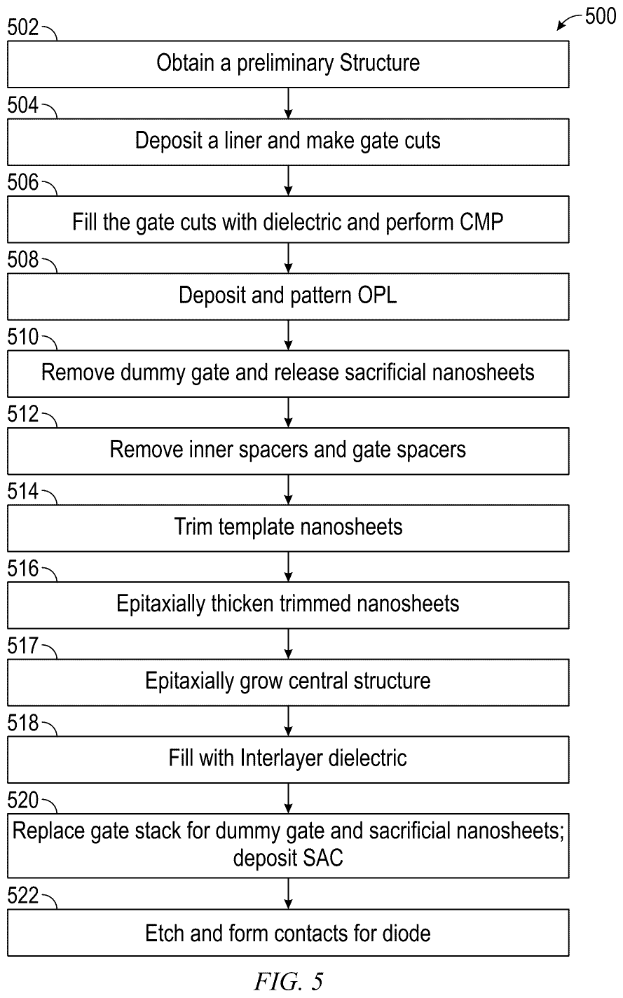

FIG. 5 depicts, in a flowchart, steps in an exemplary method 500 for fabrication of the semiconductor structure 100 that is shown in FIG. 1. Semiconductor device manufacturing includes various steps of device patterning processes. For example, the manufacturing of a semiconductor chip may start with a plurality of CAD (computer aided design) generated device patterns, which will be replicated on a substrate. The replication process may involve the use of various exposing techniques and a variety of subtractive (etching) and/or additive (deposition) material processing procedures.

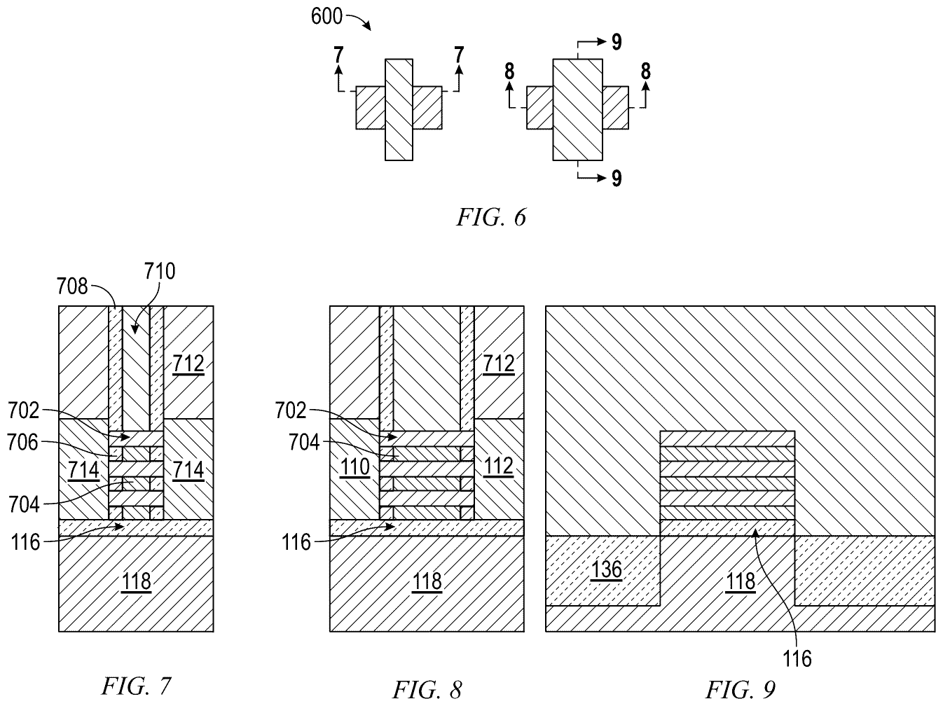

At step 502 of the method 500, obtain a preliminary structure 600, as shown in FIG. 6 through FIG. 9. FIG. 7, FIG. 8, and FIG. 9 are taken along view lines 7, 8, and 9, respectively, in FIG. 6. The structure 600 includes left and right blocks 110, 112, bottom dielectric isolation 116, substrate 118, template nanosheets 702, sacrificial nanosheets 704, inner spacers 706, gate spacers 708, dummy gates 710, and an interlayer dielectric (ILD) 712. The structure 600 is shown after epitaxial growth of the source/drain structures 714 in the transistor 104, formation of the dummy gates 710, deposition of the ILD 712, and chemical mechanical planarization.

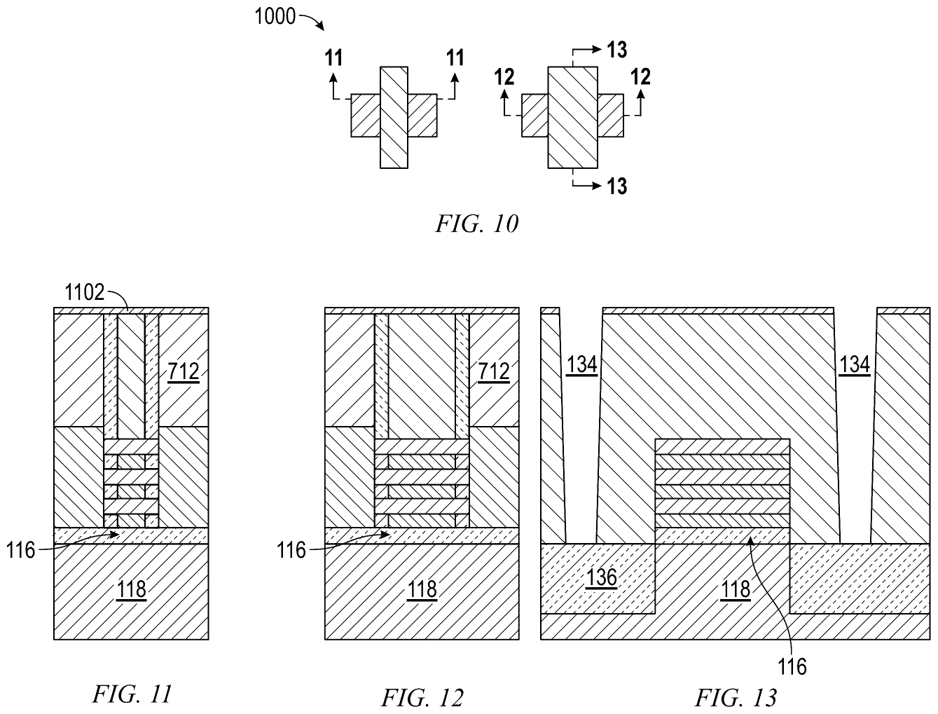

At 504 (referring to FIG. 10 through FIG. 13; FIG. 11, FIG. 12, and FIG. 13 are taken along view lines 11, 12, and 13, respectively, in FIG. 10), deposit a liner 1102 (e.g., silicon carbide) and make gate cuts 134 to form an intermediate structure 1000. There are numerous techniques used by those skilled in the art to remove material at various stages of creating a semiconductor structure, such as step 504 of making the gate cuts. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

As an exemplary subtractive process, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

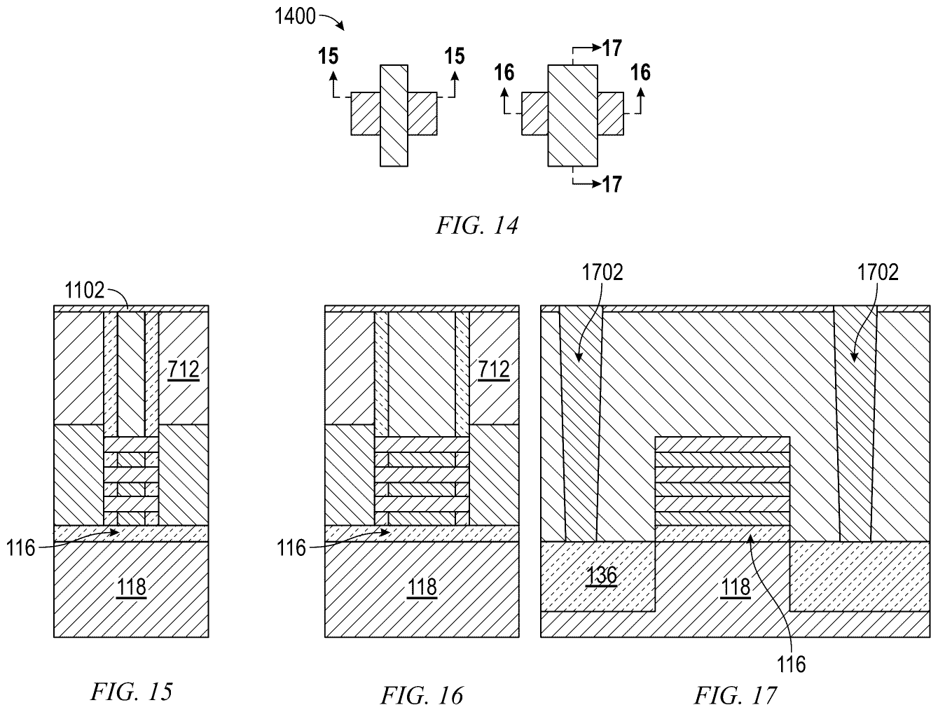

At 506 (referring to FIG. 14 through FIG. 17; FIG. 15, FIG. 16, and FIG. 17 are taken along view lines 15, 16, and 17, respectively, in FIG. 14), fill the gate cuts 134 with dielectric 1702 and perform chemical mechanical planarization (CMP) to form an intermediate structure 1400.

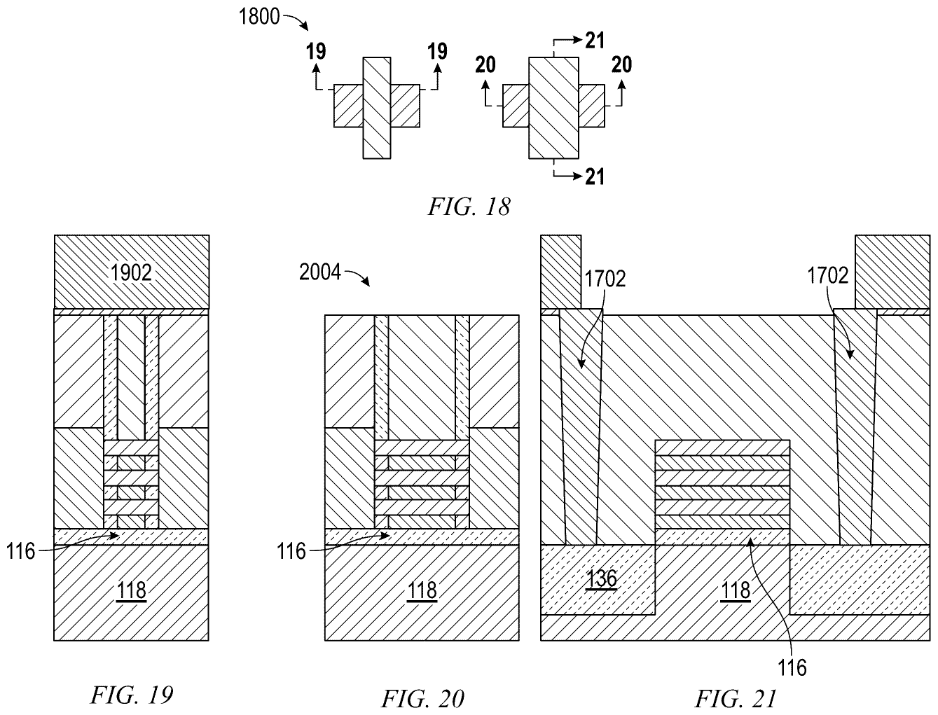

At 508 (referring to FIG. 18 through FIG. 21; FIG. 19, FIG. 20, and FIG. 21 are taken along view lines 19, 20, and 21, respectively, in FIG. 18), deposit and pattern a mask layer, such as an organic planarization layer (OPL) 1902 that exposes the region 2004 where the diode 100 will be formed, thereby forming an intermediate structure 1800.

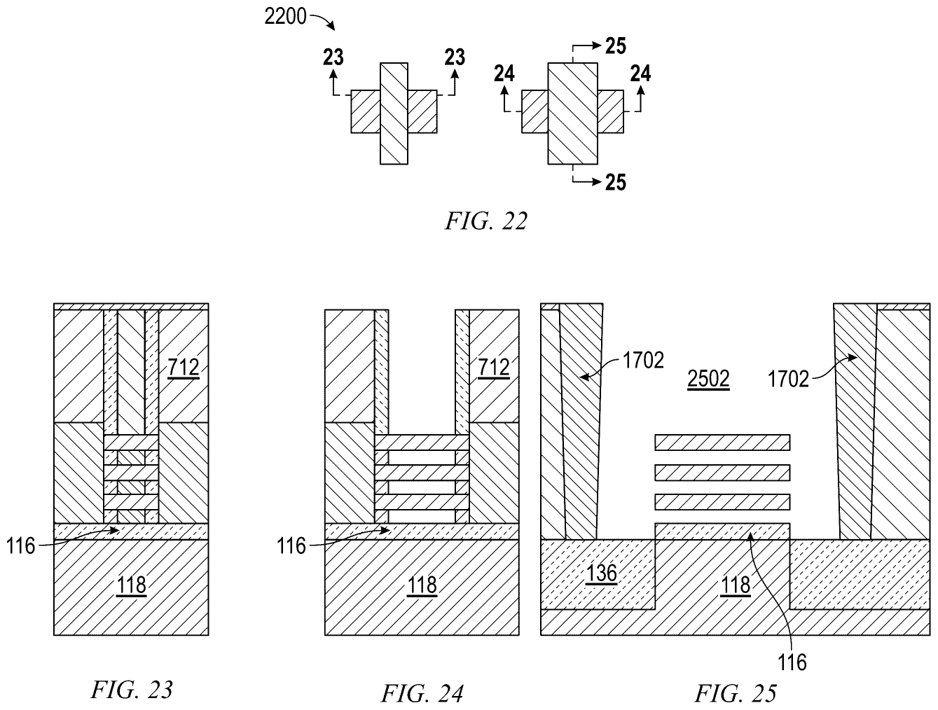

At 510 (referring to FIG. 22 through FIG. 25; FIG. 23, FIG. 24, and FIG. 25 are taken along view lines 23, 24, and 25, respectively, in FIG. 22), remove the dummy gate 710 from the diode precursor region 2004, and release the sacrificial nanosheets 704 from the diode precursor region 2004, thereby forming an intermediate structure 2200 that has a void 2502.

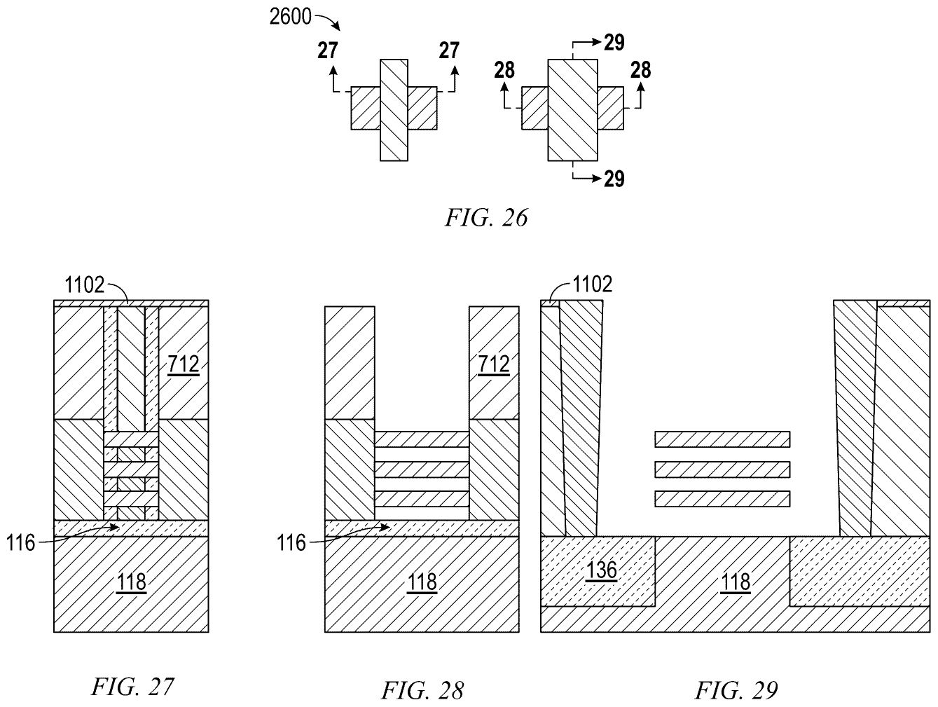

At 512 (referring to FIG. 26 through FIG. 29; FIG. 27, FIG. 28, and FIG. 29 are taken along view lines 27, 28, and 29, respectively, in FIG. 26), remove the inner spacers 706 and the gate spacers 708 from the diode precursor region 2004, thereby forming an intermediate structure 2600. In one or more embodiments, removing the spacers can be accomplished more easily if the liner 1102 is a different material than the inner spacer and gate spacers materials. For example, if the spacers 706, 708 are nitride-based, then the spacers can be wet etched selective to the liner 1102 if the liner 1102 is carbide-based (e.g., SiC or SiOC), and vice versa.

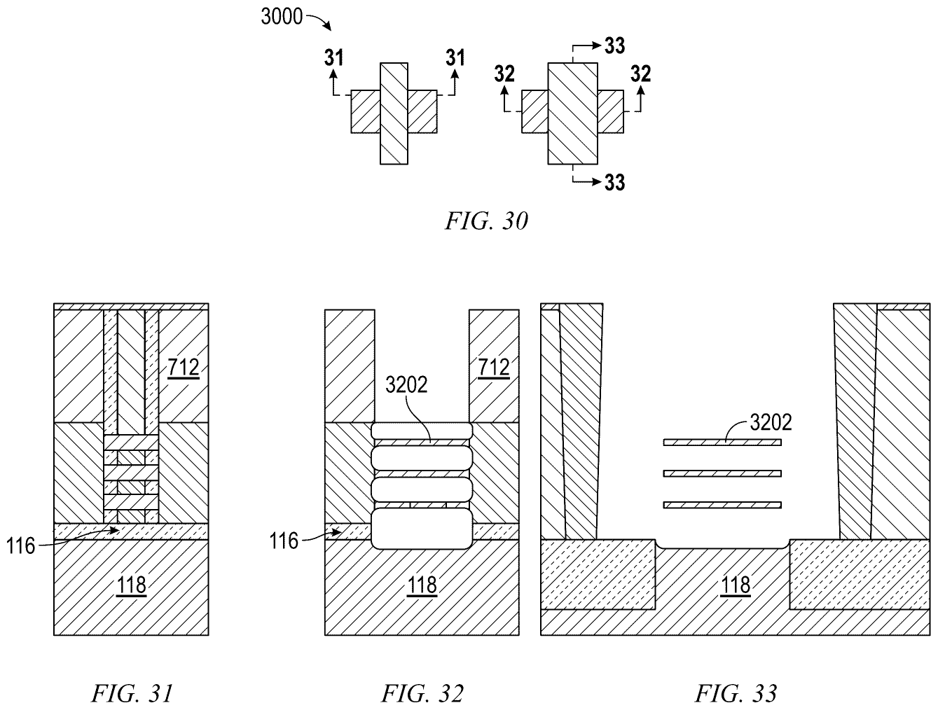

At 514 (referring to FIG. 30 through FIG. 33; FIG. 31, FIG. 32, and FIG. 33 are taken along view lines 31, 32, and 33, respectively, in FIG. 30), trim the template nanosheets 702 only within the diode precursor region 2004, thereby forming an intermediate structure 3000 that includes trimmed nanosheets 3202. Trimming can be accomplished by various etch processes; in one or more embodiments, an isotropic process is used, e.g., a wet etch using chemistry such as a bath of acetic acid (CH₃COOH), hydrogen peroxide (H₂O₂), and hydrofluoric acid (HF).

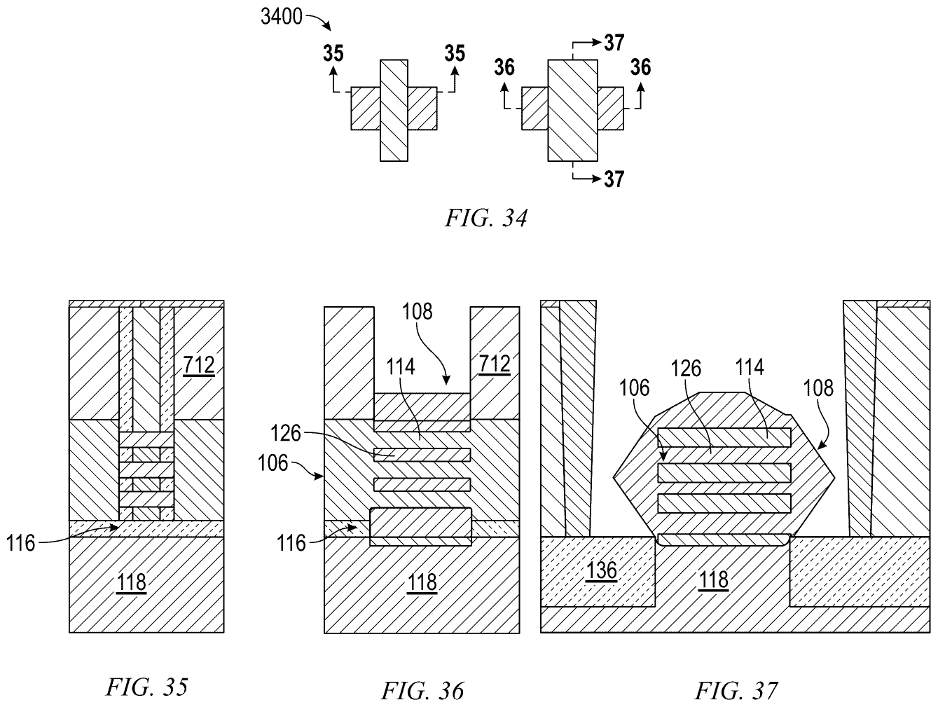

At 516 (referring to FIG. 34 through FIG. 37; FIG. 35, FIG. 36, and FIG. 37 are taken along view lines 35, 36, and 37, respectively, in FIG. 34), epitaxially grow (thicken) the trimmed nanosheets 3202 to form an intermediate structure 3400, which includes the bookend structure 106 with the nanosheets 114 that will become part of the diode 102. The nanosheets 114 can be doped in situ or by diffusion. At 517, after doping the nanosheets 114, epitaxially grow and dope the central structure 108, which includes the nanosheets 126.

Various structures that are described herein, e.g., the bookend structure and central structure including left, right, front, and rear blocks and stacks of nanosheets, may be epitaxially grown. “Epitaxy” or “epitaxial growth,” as used herein, refers to a process by which a layer of single-crystal or large-grain polycrystalline material is formed on an existing material with similar crystalline properties. One feature of epitaxy is that this process causes the crystallographic structure of the existing substrate or seed layer (including any defects therein) to be reproduced in the epitaxially grown material. Epitaxial growth can include heteroepitaxy (i.e., growing a material with a different composition from its underlying layer) or homoepitaxy (i.e., growing a material which includes the same composition as its underlying layer). Heteroepitaxy can introduce strain in the epitaxially grown material, as its crystal structure may be distorted to match that of the underlying layer. In certain applications, such strain may be desirable. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material may have the same crystalline characteristics as the deposition surface on which it may be formed. For example, an epitaxial semiconductor material deposited on a {100} crystal surface may take on a {100} orientation. In some embodiments, epitaxial growth and/or deposition processes may be selective to forming on semiconductor surfaces, and may not deposit material on dielectric surfaces, such as silicon dioxide or silicon nitride surfaces.

A number of different precursors may be used for the epitaxial deposition of the in situ doped semiconductor material. In some embodiments, the gas source for the deposition of an epitaxially formed in situ doped semiconductor material may include silicon (Si) deposited from silane, disilane, trisilane, tetrasilane, hexachlorodisilane, tetrachlorosilane, di chlorosilane, trichlorosilane, di silane and combinations thereof. In other examples, when the in situ doped semiconductor material includes germanium, a germanium gas source may be selected from the group consisting of germane, digermane, halogermane, dichlorogermane, trichlorogermane, tetrachlorogermane and combinations thereof. Examples of other epitaxial growth processes that can be employed in growing semiconductor layers described herein include rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE).

By “in-situ” it is meant that the dopant that dictates the conductivity type of doped layer is introduced during the process step, for example epitaxial deposition, that forms the doped layer. The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

As used herein, the term “conductivity type” denotes a dopant region being p-type or n-type. As further used herein, “p-type” refers to the addition of impurities to an intrinsic semiconductor that creates deficiencies of valence electrons. In a silicon-containing substrate, examples of p-type dopants, i.e., impurities include but are not limited to: boron, aluminum, gallium and indium. As used herein, “n-type” refers to the addition of impurities that contribute free electrons to an intrinsic semiconductor. Examples of n-type dopants, i.e., impurities in a silicon-containing substrate include but are not limited to antimony, arsenic and phosphorous.

In one or more embodiments, the nanosheets 114 are doped consistent with the left and right blocks 110, 112 (and the source/drain structures 714 of the transistor 104), while the central structure 108 is oppositely doped. Thus, in such embodiments, if the transistor 104 is an nFET, then the bookend structure 106 will be doped as the cathode and the central structure 108 will be doped as the anode; on the other hand, if the transistor 104 is a pFET, then the bookend structure 106 will be doped as the anode and the central structure 108 will be doped as the cathode. Note that it is not required to link the doping of the diode 102 to the doping of the transistor 104, and in one or more embodiments there may be a pFET transistor 104 with the bookend structure 106 doped as the cathode or an nFET transistor 104 with the bookend structure 106 doped as the anode.

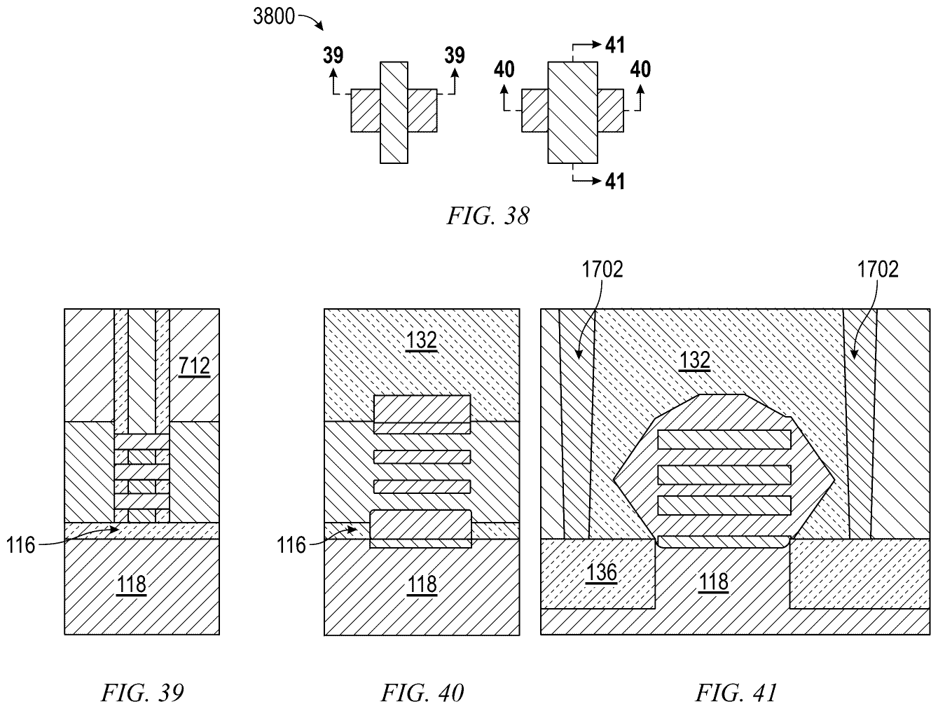

At 518 (referring to FIG. 38 through FIG. 41; FIG. 39, FIG. 40, and FIG. 41 are taken along view lines 39, 40, and 41, respectively, in FIG. 38), fill with interlayer dielectric 132 to form an intermediate structure 3800.

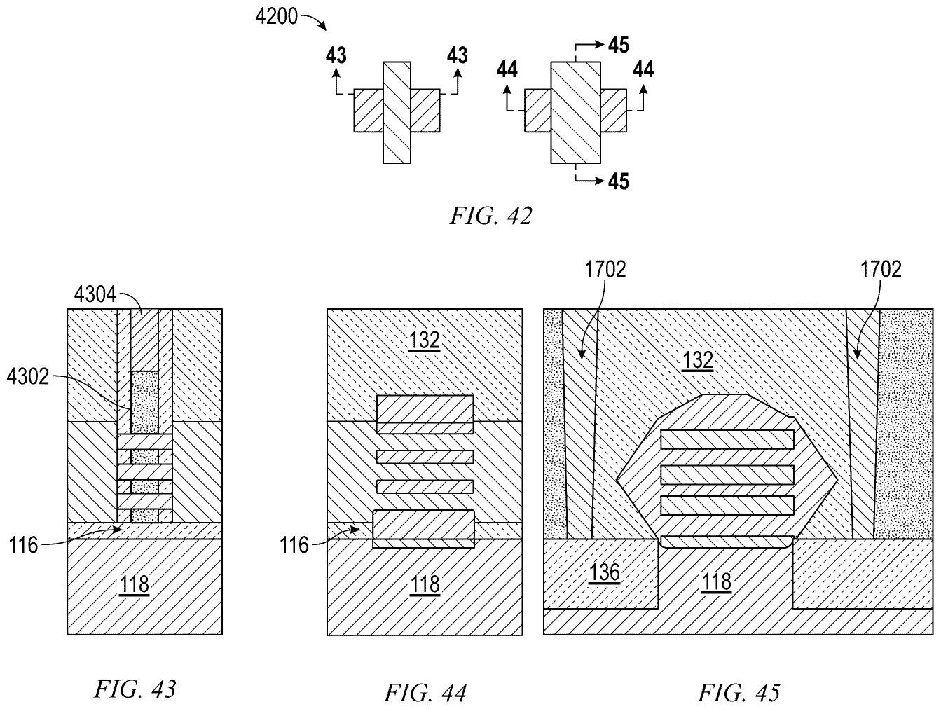

At 520 (referring to FIG. 42 through FIG. 45; FIG. 43, FIG. 44, and FIG. 45 are taken along view lines 43, 44, and 45, respectively, in FIG. 42), replace a gate stack 4302 for the sacrificial nanosheets 704 and the dummy gate 710 in the transistor 104, and deposit a self-aligned gate dielectric cap 4304 to form an intermediate structure 4200. Gate stacks in both nFET and pFET structures (in embodiments having both types of regions) include work function material (WFM) layers. Non-limiting examples of suitable work function (gate) metals include p-type work function materials and n-type work function materials. P-type work function materials include compositions such as ruthenium, palladium, platinum, cobalt, nickel, and conductive metal nitride like TiN, WN, or any combination thereof. N-type work function materials include compositions such as hafnium, zirconium, titanium, tantalum, aluminum, metal carbides (e.g., hafnium carbide, zirconium carbide, titanium carbide, and aluminum carbide), aluminides, or any combination thereof.

The work function material(s) may be deposited by a suitable deposition process, for example, ALD, CVD, PECVD, PVD, plating, and thermal or e-beam evaporation. Pinch-off of work function material between semiconductor fins is essentially avoided during deposition. The WFM layer is removed from one of the nFET and pFET regions in structures including both types of regions while the other region is protected. An SC1 etch, an SC2 etch or other suitable etch processes can be employed to remove the selected portion of the originally deposited WFM layer. A new WFM layer suitable for the region is then deposited. A device formed in the nFET region will accordingly include a WFM layer (gate electrode) having a first composition while a device in the pFET region will have a WFM layer having a second composition. For example, the WFM employed in an nFET region may be a Ti, Al, TiAl, TiAlC or TiAlC layer or a metal stack such as TiN/TiAl/TiN, TiN/TiAlC/TiN, TiN/TaAlC/TiN, or any combination of an aluminum alloy and TiN layers. The WFM layer employed in the pFET region may, for example, be a TiN, TiC, TaN or a tungsten (W) layer. The threshold voltage (Vt) of nFET devices is sensitive to the thickness of work function materials such as titanium nitride (TiN).

At 522, etch and form the contacts 120, 130 to complete the semiconductor structure 100 (referring to FIG. 1 through FIG. 4). Contact material may, for example, alternatively include tantalum (Ta), aluminum (Al), platinum (Pt), gold (Au), titanium (Ti), palladium (Pd) or any combination thereof. The contact material may be deposited by, for example, CVD, PECVD, PVD, plating, thermal or e-beam evaporation, or sputtering. A planarization process such as CMP is performed to remove any electrically conductive material (overburden) from the top surface of the structure.

Given the discussion thus far, and with reference to the accompanying figures, it will be appreciated that, in general terms, an exemplary semiconductor structure 100, according to an aspect of the invention, includes a nanosheet diode 102 that has an anode and a cathode. The nanosheet diode includes: a bookend structure 106 that is doped as one of the anode or the cathode of the diode, and that includes a left block 110, a right block 112, and a first stack of spaced-apart nanosheets 114 that horizontally connect the left and right blocks. The nanosheet diode also includes a central structure 108 that is doped as the other of the anode or the cathode of the diode, and that includes a front block 122, a rear block 124, and a second stack of nanosheets 126 that are interleaved crosswise into spaces between the first stack of spaced-apart nanosheets and that horizontally connect the front and rear blocks. The bookend structure directly contacts top, bottom, and end surfaces of the second stack of nanosheets of the central structure.

In one or more embodiments, the semiconductor structure also includes transistors adjacent to the nanosheet diode, and an interlayer dielectric that isolates the front, rear, left, and right blocks from the adjoining transistors.

In one or more embodiments, the semiconductor structure also includes a top contact 130 that is electrically connected to the central structure of the nanosheet diode. In one or more embodiments, the semiconductor structure also includes a side contact 120 that is electrically connected to the bookend structure of the nanosheet diode. In one or more embodiments, the semiconductor structure also includes bottom dielectric insulation 116 that underlies at least one of the left and right blocks of the bookend structure. In one or more embodiments, the semiconductor structure also includes a substrate 118 that is electrically connected to the bookend structure via the second nanosheet stack. In one or more embodiments, the semiconductor structure also includes gate cuts 134 that separate the front and rear blocks from adjoining gate stacks.

In one or more embodiments, the bookend structure and the central structure both consist essentially of silicon. In one or more embodiments, the anode is doped with a p-dopant selected from the list consisting of boron, aluminum, gallium and indium. In one or more embodiments, the cathode is doped with an n-dopant selected from the list consisting of antimony, arsenic and phosphorous. In one or more embodiments, the second semiconductor is the same as the first semiconductor.

According to another aspect, an exemplary method for forming a nanosheet diode includes forming a bookend structure, which includes a first semiconductor that is doped as one of an anode or a cathode of the diode, and which includes a left block, a right block, and a first stack of spaced-apart nanosheets that horizontally connect the left and right blocks; and forming a central structure, which includes a second semiconductor that is doped as the other of the anode or the cathode of the diode, and which includes a front block, a rear block, and a second stack of nanosheets that are interleaved crosswise into spaces between the first stack of spaced-apart nanosheets and that horizontally connect the front and rear blocks. The bookend structure directly contacts top, bottom, and end surfaces of the second stack of nanosheets of the central structure.

In one or more embodiments, forming the bookend structure includes, at 514, trimming undoped template nanosheets that horizontally connect the left and right blocks; at 516, epitaxially regrowing the first stack of nanosheets from the trimmed template nanosheets; and doping the first stack of nanosheets to match a doping of the left and right blocks.

In one or more embodiments, the method also includes, at 512, releasing inner spacers from positions adjacent to the left and right blocks of the bookend structure, before trimming the template nanosheets.

In one or more embodiments, doping the first stack of nanosheets comprises in situ doping. In one or more embodiments, doping the first stack of nanosheets comprises diffusion doping.

In one or more embodiments, forming the central structure includes, at 517, epitaxially growing the front, rear, and top blocks and the second stack of nanosheets from the bookend structure as a seed. In one or more embodiments, forming the central structure includes in situ doping the central structure opposite of the bookend structure. In one or more embodiments, forming the central structure includes diffusion doping the central structure opposite of the bookend structure.

In one or more embodiments, the second semiconductor is the same as the first semiconductor.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1st Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, which comprises a nanosheet diode having an anode and a cathode, wherein the nanosheet diode comprises:
a bookend structure, which comprises a first semiconductor that is doped as one of the anode and the cathode of the diode, and which comprises a left block, a right block, and a first stack of spaced-apart nanosheets that horizontally connect the left and right blocks; and
a central structure, which comprises a second semiconductor that is doped as the other of the anode and the cathode of the diode, and which comprises a front block, a rear block, and a second stack of nanosheets that are interleaved crosswise into spaces between the first stack of spaced-apart nanosheets and that horizontally connect the front and rear blocks;
wherein the bookend structure directly contacts top, bottom, and end surfaces of the second stack of nanosheets of the central structure.

2. The semiconductor structure of claim 1, further comprising:
transistors adjacent to the nanosheet diode; and
an interlayer dielectric that isolates the front, rear, left, and right blocks from the adjoining transistors.

3. The semiconductor structure of claim 1, further comprising:
a top contact that is electrically connected to the central structure of the nanosheet diode.

4. The semiconductor structure of claim 1, further comprising:
a side contact that is electrically connected to the bookend structure of the nanosheet diode.

5. The semiconductor structure of claim 1, further comprising:
bottom dielectric insulation that underlies at least one of the left and right blocks of the bookend structure.

6. The semiconductor structure of claim 1, further comprising:
a substrate that is electrically connected to the bookend structure via the second nanosheet stack.

7. The semiconductor structure of claim 1, further comprising:
gate cuts that separate the front and rear blocks from adjoining gate stacks.

8. The semiconductor structure of claim 1, wherein the bookend structure and the central structure both consist essentially of silicon.

9. The semiconductor structure of claim 8, wherein the anode is doped with a p-dopant selected from the list consisting of boron, aluminum, gallium and indium.

10. The semiconductor structure of claim 8, wherein the cathode is doped with an n-dopant selected from the list consisting of antimony, arsenic and phosphorous.

11. The semiconductor structure of claim 1, wherein the second semiconductor is the same as the first semiconductor.

12. A method for making a nanosheet diode, the method comprising:
forming a bookend structure, which comprises a first semiconductor that is doped as one of an anode and a cathode of the diode, and which comprises a left block, a right block, and a first stack of spaced-apart nanosheets that horizontally connect the left and right blocks; and
forming a central structure, which comprises a second semiconductor that is doped as the other of the anode and the cathode of the diode, and which comprises a front block, a rear block, and a second stack of nanosheets that are interleaved crosswise into spaces between the first stack of spaced-apart nanosheets and that horizontally connect the front and rear blocks;
wherein the bookend structure directly contacts top, bottom, and end surfaces of the second stack of nanosheets of the central structure.

13. The method of claim 12, wherein forming the bookend structure comprises:
trimming undoped template nanosheets that horizontally connect the left and right blocks;
epitaxially regrowing the first stack of nanosheets from the trimmed template nanosheets; and
doping the first stack of nanosheets to match a doping of the left and right blocks.

14. The method of claim 13, further comprising:
releasing inner spacers from positions adjacent to the left and right blocks of the bookend structure, before trimming the template nanosheets.

15. The method of claim 12, wherein doping the first stack of nanosheets comprises in situ doping.

16. The method of claim 12, wherein doping the first stack of nanosheets comprises diffusion doping.

17. The method of claim 12, wherein forming the central structure comprises:
epitaxially growing the front, rear, and top blocks and the second stack of nanosheets from the bookend structure as a seed.

18. The method of claim 17, wherein forming the central structure comprises:
in situ doping the central structure opposite of the bookend structure.

19. The method of claim 17, wherein forming the central structure comprises:
diffusion doping the central structure opposite of the bookend structure.

20. The method of claim 12, wherein the second semiconductor is the same as the first semiconductor.
